(19) United States
(12) Patent Application Publication
(10) Pub. No.: US 2005/0054211 A1
(43) Pub. Date: Mar. 10, 2005

(54) Purification of silicon-containing materials

(76) Inventors: Mindi Xu, Naperville, IL (US); Tay Sayasane, Aurora, IL (US); Jean-Marc Girard, Paris (FR)

Correspondence Address: Air Liquide;Intellectual Property Department, Ste. 1800, 2700 Post Oak Blvd, Houston, TX, 77056, US

(21) Appl. No.: 10/879,530

(22) Filed: Jun. 30, 2004

Related U.S. Application Data
(60) Provisional application No. 60/500,214, filed on Sep. 4, 2003.

(51) Int. Cl. H01L 21/311; H01L 21/302; H01L 21/461

(52) U.S. Cl. 438/745

(57) ABSTRACT

Systems and methods of purifying a silicon-containing material include the step of directing the silicon-containing material in a liquid state through an adsorption unit including an adsorbent material to facilitate adsorption of at least one component from the silicon-containing material. Alternatively, the silicon-containing material is directed, in liquid state and/or gaseous state, through two or more purification units, including an adsorption unit, a vaporization unit, a filter unit and a condenser. The silicon-containing material can be a low-k silicon-containing material such as trimethylsilane, tetramethylsilane, dimethyldimethoxysilane, tetramethylcyclotetrasiloxane, octamethylcyclotetrasiloxane, dimethylphenyl silane, and dimethyldivinyl silane.

### CROSS-REFERENCE TO RELATED APPLICATIONS

This application claims priority from U.S. Provisional Patent Application Ser. No. 60/500,214, entitled “Method for Purification of Organosilicate Compounds”, and filed Sep. 4, 2003. The disclosure of this provisional patent application is incorporated herein by reference in its entirety.

### BACKGROUND OF INVENTION

1. Field of Invention

The present invention pertains to methods and systems for purifying silicon-containing compounds for use in semiconductor manufacturing processes.

2. Related Art

As the size of integrated circuit chips decreases, semiconductor manufacturers are searching for viable materials to deposit thin films with lower dielectric constant (low-k) values of the interconnect system. A low dielectric constant is critical to advanced semiconductor manufacturing because it allows metal lines to be packed closer together on a chip with less risk of electrical signal leakage between adjacent layers. These types of materials are typically much less dense than silicon dioxide (having a dielectric constant of 3.9) and fluorinated silicon glass (having a dielectric constant of about 3.6 to 3.8), the materials that have been commonly used for years in semiconductor chip manufacturing processes. Currently, manufacturers are interested in utilizing materials for such manufacturing processes where the dielectric constant value of the material is below 2.9 to facilitate shrinking of the size of semiconductor ships as well as to boost chip performance.

Certain compounds have been screened as potential prominent candidates of low-k materials in semiconductor manufacturing processes, including silicon-containing compounds such as trimethylsilane, tetramethylsilane, dimethyldimethoxysilane, tetramethylcyclotetrasiloxane, octamethylcyclotetrasiloxane, dimethylphenyl silane, and dimethyldivinyl silane.

These compounds invariably take the form of tetravalent silicon and grow low-k films with the presence of organic groups, typically methyl (CH₃) groups. It is believed that the presence of an organic methyl group in the film makes the resultant film porous with a low dielectric constant. In addition, with the exception of trimethylsilane, these chemical materials are in the form of liquid at normal room temperature and pressure conditions.

While the above-referenced silicon-containing materials are commercially available, they are generally in an unacceptable condition for semiconductor processing applications. In particular, these materials typically contain different metal and organic impurities with rather high concentrations, depending on the production processes utilized to form the materials. These metal and organic impurities are fatal to the thin film in terms of the film quality and dielectric constant value. For example, metal impurities will significantly increase the dielectric constant value of the deposited film and, even worse, will shorten adjacent layers of the chips. Similarly, the organic impurities existing in the low-k materials will change the dielectric values and thermo-mechanic properties of the deposited films. Therefore, low-k silicon-containing materials must be substantially pure (e.g., at an ultra-pure concentration level of at least about 99.99%). Thus, raw materials for low-k film deposition must be purified to remove metal and organic impurities prior to being utilized in a semiconductor manufacturing process.

Traditional purification methods such as adsorption and distillation have been used to purify chemical materials for semiconductor manufacturing processes. For example, U.S. Pat. No. 6,444,013 to Helly et al., the disclosure of which is incorporated herein by reference in its entirety, describes a method of purifying methylsilane by adsorbing impurities such as hydrogen, nitrogen, argon, oxygen, methane, carbon dioxide, silane, chlorosilane, and dimethylsilane in an adsorption unit containing an adsorbent such as magnesium silicate and at a controlled low temperature, followed by collecting purified methylsilane by condensation. While this method is effective for purifying methylsilane, it is ineffective for purifying low-k silicon-containing materials such as trimethylsilane, tetramethylsilane, dimethyldimethoxysilane, tetramethylcyclotetrasiloxane, octamethylcyclotetrasiloxane, dimethylphenyl silane, and dimethyldivinyl silane. In particular, due to their physiochemical properties, these materials will quickly saturate the adsorbent material disclosed in Helly et al., thus rendering the purification process ineffective.

In U.S. Pat. No. 5,493,043 to Marko, a method is described in which an alumina bed is provided for removing impurities including olefins and chlorocarbons from a methylsilane mixture at a controlled temperature greater than about 150° C. While effective in removing impurities from methylsilane, this method would be rather costly when utilized with low-k silicon-containing materials, in particular materials that exist in liquid state at ambient temperature and pressure conditions, such as trimethylsilane, tetramethylsilane, dimethyldimethoxysilane, tetramethylcyclotetrasiloxane, octamethylcyclotetrasiloxane, dimethylphenyl silane, and dimethyldivinyl silane.

Various purifiers are also commercially available for purifying trimethylsilane while in gas form at standard conditions, such as purifiers available from Mykrolis Corporation (Bedford, Mass.). These purifiers contain aluminum oxide as support material and magnesium hydride as reactive material to remove moisture and oxygen in trimethylsilane gas. While these purifiers are effective in purifying trimethylsilane gas, they are not effective for certain low-k silicon-containing materials in liquid form, because these materials will react with the reactive metal hydride to produce a hydrogen by-product, thus creating an undesirable impurity during the purification process.

In U.S. Pat. No. 5,290,342 to Wikman et al., silane and ethylsilane can be separated with a specially treated carbon bed that is heated at a controlled pressure before its use. The mixture of silane and ethylsilane is directed through the specially treated carbon bed for separation, and the heavier molecule ethylsilane is adsorbed into the carbon. The carbon bed of Wikman et al. may not be useful for purifying low-k silicon-containing materials, especially liquid silicon-containing materials at ambient temperatures and pressures, since the low-k silicon-containing materials will likely be adsorbed with other organic impurities into the carbon, thus making the adsorption separation ineffective.

Purification of low-k silicon-containing materials for semiconductor manufacturing must be based upon a proper process and method. Such a purification system must remove the impurities in various forms, including solid, organic, and inorganic impurities. At the same time, the purification system must not contribute any impurities of reaction by-product or shedding and leaching origination to the material being purified.

### SUMMARY OF THE INVENTION

It is an object of the present invention to purify silicon-containing materials, preferably low-k silicon containing materials, to a selected degree of purity, preferably about 99.99% by weight or greater.

It is another object of the present invention to prevent the incorporation of additional impurities into the silicon-containing material while the material is being purified.

It is a further object of the present invention to purify low-k silicon materials in liquid state at standard room temperatures and pressures.

The aforesaid objects are achieved individually and/or in combination, and it is not intended that the present invention be construed as requiring two or more of the objects to be combined unless expressly required by the claims attached hereto.

In accordance with the present invention, a system and method of purifying a silicon-containing material includes directing the silicon-containing material in a liquid state through an adsorption unit including an adsorbent material to facilitate adsorption of at least one component from the silicon-containing material. Optionally, the system and method further includes directing the silicon-containing material through additional purification units, including a filter unit, a vaporization unit and a condenser. The system and method can also include one or more by-pass features where one or more of the purification units can be selectively by-passed during system operation.

In another embodiment of the present invention, a system and method of purifying a silicon-containing material includes directing the silicon-containing material through at least two of the following: an adsorption unit including an adsorbent material to facilitate adsorption of at least one component from the silicon-containing material, a filter unit to remove particulate material from the silicon-containing material, a vaporization unit to facilitate at least partial vaporization of the silicon-containing material stream to form a silicon-containing material vapor stream, and a condenser to condense the silicon-containing material from a vapor state to a liquid state.

The arrangement of purification units can be in any selected order. For example, the adsorption unit can be arranged at a downstream location from the vaporization unit, such that the silicon-containing material stream is in a vapor state as it is processed within the adsorption unit. Alternatively, the adsorption unit can be arranged at an upstream location from the vaporization unit, where the silicon-containing material stream is in a liquid state during processing within the adsorption unit. The system can include one or more by-pass features to facilitate by-pass of one or more of the purification units during system operation.

Preferably, the silicon-containing material is a low-k material including at least one of trimethylsilane, tetramethylsilane, dimethyldimethoxysilane, tetramethylcyclotetrasiloxane, octamethylcyclotetrasiloxane, dimethylphenyl silane, and dimethyldivinyl silane.

The above and still further objects, features and advantages of the present invention will become apparent upon consideration of the following detailed description of specific embodiments thereof, particularly when taken in conjunction with the accompanying drawings wherein like reference numerals in the figures are utilized to designate like components.

### BRIEF DESCRIPTION OF THE DRAWINGS

FIG. 1 is a diagram of a purification system for purifying a silicon-containing compound in accordance with the present invention.

FIG. 2 is an alternative embodiment of a diagram of a purification system for purifying a silicon-containing compound in accordance with the present invention.

### DESCRIPTION OF PREFERRED EMBODIMENTS

In accordance with the present invention, methods and corresponding systems are disclosed herein for purifying silicon-containing materials to a suitable purity level for use in semiconductor manufacturing processes. As used herein, the term “low dielectric constant” or “low-k” with respect to certain material refers to a material having a dielectric constant value no greater than about 3.9. Accordingly, the silicon-containing materials that are purified in accordance with the present invention preferably are low-k compounds that have a dielectric constant of no greater than about 3.9, more preferably no greater than about 2.9. However, it is noted that any silicon-containing materials (i.e., low-k or not low-k) can be purified in accordance with the present invention.

The impurities in silicon-containing raw materials typically include one or more of the following: one or more types of organic compounds (e.g., compounds such as tetrahydrofuran, benzene, toluene, octane, methanol, ethanol, methyl butene, pentanes such as methyl pentane, butanes such as dimethyl butane and trimethyl butane, and organic halogenates), one or more types of metallic elements (e.g., aluminum, sodium, calcium, zinc, iron, nickel, chromium, etc.) and metallic compounds, one or more types of dissolved gases (e.g., nitrogen, carbon dioxide, carbon monoxide, etc.), various particulate materials, and water moisture. Each type of impurity can exist in the material at a concentration varying about one part per million (1 ppm) or greater to a few thousand ppm. Particles in the raw materials can vary from about a few hundred micrometers in diameter or larger to smaller sizes such as about 1 micrometer in diameter or smaller.

The present invention provides a purification system including at least one of an adsorption unit to remove organic impurities and moisture, a filtration device to remove solid from the chemical solutions, a vaporization unit to remove metallic and non-volatile impurities, and/or a packed bed or column to facilitate countercurrent contact between liquid and silicon-containing gaseous materials that results in purification of the silicon-containing gaseous materials. Optionally, the purification system may further include a distillation column to facilitate removal of certain impurities from silicon-containing materials based upon differences in boiling points of the materials.

In one embodiment of the present invention, low-k silicon containing compounds are purified as liquids and at standard or ambient temperatures and pressures, where ambient conditions are in the temperature range of about 0° C. to about 35° C. and a pressure range of about 50 kPa to about 200 kPa. Exemplary low-k silicon containing compounds that are effective in forming films during semiconductor manufacturing and that are liquids at ambient temperature and pressure conditions include, without limitation, trimethylsilane, tetramethylsilane, dimethyldimethoxysilane, tetramethylcyclotetrasiloxane, octamethylcyclotetrasiloxane, dimethylphenyl silane, and dimethyldivinyl silane. In particular, such compounds are purified in a liquid state by adsorption within the adsorption unit.

In other embodiments of the present invention, silicon-containing compounds are purified (in liquid and/or gaseous state) utilizing any one or combination of processing steps including adsorption, filtration, vaporization, absorption and/or distillation. The selection of one or more of these processing steps will depend upon the amount and types of impurities in the raw material to be processed that includes the silicon-containing compound of interest.

An adsorption bed or unit can be provided to remove certain impurities such as organic compounds and moisture from the silicon-containing material being processed. The adsorption unit can be configured to receive silicon-containing raw materials from a suitable supply source (e.g., storage containers), where the matierals are delivered with a pump or through pressurization with a high pressure inert gas to the adsorption unit. Suitable adsorbents that can be used in an adsorption unit are synthetic adsorbent beads (e.g., hydrophobic beads for adsorbing organic compounds and hydrophilic beads for adsorbing water), activated carbon, and molecular sieves.

A filter device can be provided in the purification system downstream from the adsorption unit to remove particulate impurities from the silicon-containing material that exits the adsorption unit (in a liquid or a gaseous state). The filter device can be a separate device or, alternatively, combined or integrated with to form a portion of the adsorption unit. It is particularly desirable in certain systems to provide a filter device at a downstream location from the adsorption unit to facilitate not only the removal of particulate impurities from the material stream, but also to prevent the entrainment of adsorbent particles within the material stream and removal of the adsorbent particles from the adsorption unit.

A vaporization unit can be provided downstream from the filter to receive the silicon-containing materials in order to facilitate the removal of additional organic impurities, moisture, as well as metal and/or metal compound impurities. The silicon-containing materials are vaporized and exit the vaporization unit in a gaseous state, leaving heavy impurities behind inside the vaporization unit. The gaseous stream exiting the vaporization unit can then be directed to a condenser to condense the gaseous stream to its liquid state. Any light impurities that are not be condensed in the condenser can be released from the condenser in an exhaust stream.

The condensed silicon-containing materials can be directed from the condenser to a storage container for use in semiconductor processing applications. Optionally, depending upon the amount and types of impurities within the silicon-containing materials, the material stream can be selectively directed through only certain portions of the purification system, thus by-passing certain portions that are unnecessary for a particular application. Further, systems can be designed such that purified silicon-containing materials are supplied directly to semiconductor manufacturing systems for direct processing of the purified product (i.e., rather than directing the purified product to a storage container or vessel). The purified silicon-containing material product can be utilized for depositing low-k films by a variety of well-known or other suitable deposition methods, such as chemical vapor deposition (CVD), spill on methods, etc.

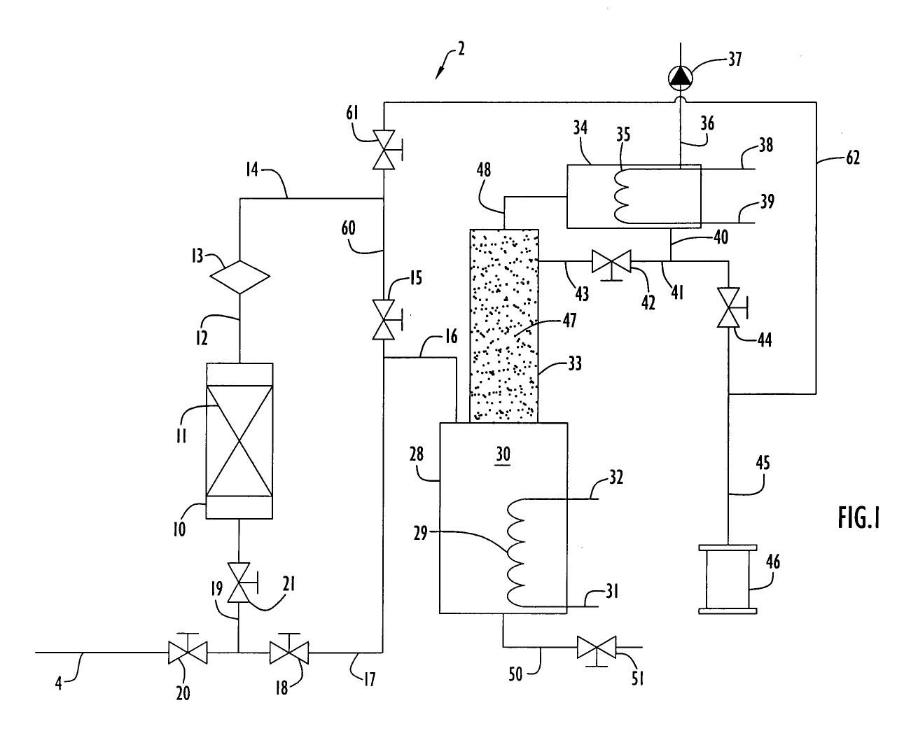

An exemplary embodiment of a purification system that includes an adsorption unit, a filter, a vaporization unit and a condenser in the manner generally described above is depicted in FIG. 1. In particular, a purification system 2 receives raw material from a supply source (e.g., a raw material container, not shown) via a conduit or supply line 4. The raw material includes a low-k silicon-containing material preferably in liquid state (e.g., any of the materials described above) along with one or more impurities such as any of those described above. The raw material is pumped from the supply source (e.g., via an inert gas such as nitrogen or helium). A valve 20 is provided along the supply line 4 to facilitate selective isolation of the purification system 2 from the raw material supply source.

An adsorption unit 10 is connected at its inlet to the supply line 4 at a location downstream from the valve 20 and via a branch line 19. A valve 21 is provided along the branch line 19 to selectively isolate the adsorption unit 10 from the supply line 4 during system operation. In addition, a valve 18 is disposed along supply line 4 at a location downstream from the branch line 19 to facilitate flow of fluid from the supply line 4 to a flow line 17 that leads to a vaporization unit 28 as described below. The flow line 17 facilitates a by-pass of the adsorption unit 10 for the material stream when valve 21 is closed and valve 18 is opened.

An adsorbent material 11 is packed within the adsorption unit 10 to facilitate removal of impurities such as organic materials and water from the low-k silicon-containing material. Exemplary operating temperatures within the adsorption unit are from the freezing point temperatures to the boiling point temperatures of the silicon-containing materials being utilized, preferably about 0° C. to about 50° C., more preferably about 0° C. to about 30° C. Exemplary operating pressures within the adsorption unit are preferably from about 50 kPa to about 500 kPa, more preferably from about 80 kPa to about 300 kPa. As previously noted, the temperature and pressure ranges are most preferably in ambient ranges such that the silicon-containing material is in a liquid state as it is processed within the adsorption unit.

The adsorption unit can be constructed of any suitable materials including, without limitation, stainless steel, plastics, quartz, glass, and other metals. In particular, it is noted that the construction materials for the adsorption unit, vaporization unit, condenser, and other components of the system are preferably compatible with the chemical compounds making up the material to be purified and further minimize or prevent the leaching of impurities into the processed material. The adsorption unit can further have a cylindrical, rectangular or any other suitable shape and is suitably dimensioned to provide a sufficient volume capacity to hold a sufficient amount of adsorbent material within the bed. It is to be understood that the dimensions of the adsorption unit will depend upon the flow rate and impurity concentrations of the low-k silicon containing material to be processed within the adsorption unit. For example, the adsorption unit can be cylindrical, with a length of about at least about 15 centimeters (about 6 inches) and a diameter of at least about 0.635 centimeter (about 0.25 inch). Preferably, the adsorption unit has a length of at least about 30.5 centimeters (about 12 inches) and a diameter of at least about 2.54 centimeters (about 1 inch). Providing an adsorption unit with the dimensions as described above will facilitate effective processing of raw material at flow rates of at least about 10 milliliters per minute.

One or more suitable adsorbent materials can be selected for use within the adsorption unit to facilitate effective adsorption of impurities such as organic compounds and/or moisture. Exemplary adsorbents include, without limitation, activated carbon materials, molecular sieves, zeolite, and synthetic adsorbents. Preferred adsorbents are pyrolyzed carbonaceous adsorbent materials that are regenerable, in particular carbonaceous adsorbent materials formed by pyrolysis of highly sulfonated styrene-divinylbenzene macroreticular ion exchange resins. Examples of such adsorbent materials are those commercially available from Rohm & Haas (Philadelphia, Pa.) under the following trade names: Ambersorb® 563, Ambersorb® 572, and Ambersorb® 600. The Ambersorb® 563 adsorbent is the most preferred adsorbent material for liquid phase adsorption of organic impurities, and this adsorbent has been found to effectively adsorb organic compounds such as toluene, benzene, tetrahydrofuran, 2,2,3-trimethyl decane, cyclopentanone, and hexyloctyl ether. The Ambersorb® 600 adsorbent is particularly useful in vapor phase adsorption of organic impurities. These adsorbent materials are in the form of beads that can be mixed and installed in a single adsorption unit for removing organic impurities and moisture.

A filtration device 13 is disposed downstream from the adsorption unit 10 along an outlet line 12 extending from the unit. The filtration device can be a cartridge filter with a plastic membrane or include synthetic metal filter media. The cartridge filter could further be of a disposable type or a changeable type such as those commercially available from Pall Corporation (East Hills, N.Y.) or Mykrolis Corporation (Bedford, Mass.). Alternatively, two or more filters could be installed in parallel (so as to facilitate a backup filter when one filter needs replacing) or in series. When two or more filters are installed in parallel, valves can be installed at appropriate upstream and downstream locations from each filter to selectively isolate each filter from system flows to facilitate changing of a filter during system operation. Preferably, the filtration device includes an electron polished stainless steel housing and includes a pore size of no greater than about 0.5 micrometer.

The chemical fluid exiting the filtration device 13 is directed into a flow line 14 that connects with a branch line 60 in a T-branch configuration. Branch line 60 is connected at one downstream location from line 14 to a valve 61, which is in turn connected with a flow line 62 that directs fluid flow to a flow line 45 and to a container 46 to facilitate by-pass of fluid flow into the vaporization unit 28 as described below. In addition, branch line 60 is connected at another downstream location from line 14 to a valve 15, which is in turn connected to the flow line 17 (such that the flow line 17 extends between valves 15 and 18).

A flow line 16 branches from the flow line 17 and is connected to an inlet of a vaporization unit 28. The vaporization unit 28 includes a vaporization chamber 30 with a heating element 29 disposed therein, and a flow channel or chamber 33 disposed immediately downstream from the vaporization chamber 30. A flow line 48 connects the vapor outlet of the flow chamber 33 to an inlet of a condenser 34. The material stream entering the vaporization unit 28 is vaporized within the chamber 30 and travels in an upward direction into chamber 33 and to the condenser 34 via the flow line 48. The flow chamber 33 is configured to allow vapor to flow upward from the vaporization chamber 30 to the condenser 34 while simultaneously allowing condensate liquid to flow from the condenser downward and back toward the vaporization chamber 30 via flow lines 40 and 41 as described below.

The condenser 34 includes a heating element 35 disposed within the condenser. The heating elements 29 and 35 of the vaporization unit 28 and the condenser 34 are similar in design and configuration. Exemplary heating elements for vaporizing fluids within the vaporization chamber 30 include coil type heat exchangers, water heating baths and/or electric heaters. A coil type heat exchanger, as described by heating element 29 in FIG. 1, is most preferable due to its ease of use and safety features. Heating fluid (i.e., a heated fluid such as water or oil) flows from line 31 into the coil 29 and out of the coil via line 32. Similarly, coolant flows into a coil heat exchanger 35 of the condenser 34 via inlet and outlet lines 38 and 39. The heat exchanger coils can be installed inside the vaporization unit and condenser (as depicted in FIG. 1) to facilitate direct contact with fluid flowing within the chambers or, alternatively, outside of the chambers to provide heat energy to the fluid inside the chambers. Preferably, the operating temperatures and pressures within the vaporization chamber 30 are in the ranges of about the low-k silicon-containing material boiling temperature at the system pressure, while the operating temperatures and pressures within the condenser 34 are in the ranges of below the boiling temperature (preferably by about 1° C. or more) of the low-k silicon-containing material at the system pressure. For example, when the low-k silicon-containing material that is processed is tetramethyl silane, the operating temperature in the vaporization chamber is preferably in the range of about 27° C. to about 35° C., at a system pressure in the range of about 110 kPa to about 130 kPa. The operating temperature of the condenser for this material is preferably below about 27° C., and more preferably in the range of about 15° C. to about 25° C., at a system pressure of about 100 kPa.

A drain line 50 is connected at a lower location of the vaporization unit 28 and includes a valve 51 disposed along the drain line 50. The drain line 50 extends to an impurities collection unit (not shown). As the system operates, organic and/or metal compound impurities that do not vaporize within the vaporization chamber 30 accumulate at the bottom of the chamber 30. The valve 51 is selectively opened to drain such impurities from the chamber 30 for collection at the impurities collection unit.

An exhaust line 37 is connected to the condenser 34 to facilitate venting of non-condensed gases and volatile impurities from the condenser to achieve further purification of the condensed silicon-containing material within the condenser. The line 36 includes a one-way check valve 37 to vent gas from the condenser while prohibiting backflow of fluid into the condenser via line 36.

Condensed liquid products are directed from an outlet of the condenser 34 to a flow line 40. The flow line 40 extends to a branch line 41 that in turn connects at each of its ends with valves 42 and 44. Valve 42 is disposed at a downstream location from the flow line 40 and connects the flow line 40 with a flow line 43. The flow line 43 connects with the flow chamber 33. Valve 44 is disposed at a downstream location from the flow line 40 and connects flow line 41 with a flow line 45. Flow line 45 also connects with a product container 46, and the by-pass line 62 that extends from the valve 61 connects with line 45 at a location downstream from the valve 44.

Thus, the flow line 40 directs purified and condensed silicon-containing product from the condenser 34 to the product container 45 when valve 44 is open. In addition, the opening and closing of valves 42 and 44 permits selective flow of condensed product exiting the condenser 34 to flow back into the chamber 33 and into the vaporization unit 28. In certain situations, it may be desirable to direct a selected portion of condensed liquid product including purified low-k silicon-containing compounds to flow to the product container 46, while also permitting some condensed liquid product to flow back to into the flow chamber 33. For example, in system start-up situations as well as when impurity concentrations within the condensate are high, it may be desirable to direct a selected portion (e.g., some or all) of the condensate flow back to the vaporization chamber.

The flow channel 33 is optionally loaded with packing materials 47 to form a packed bed within the flow channel 33 to increase the residence time of condensed liquid and gaseous fluid flowing in countercurrent directions through the channel 33, thus increasing the potential for mass exchange and absorption of impurities from the gaseous fluid to the condensed liquid as the gaseous fluid flows to the condenser 34. The condensed liquid is preferably distributed at the top of the packing section inside the flow channel 33 (e.g., via a manifold disposed near the top or vapor outlet portion of the flow channel).

The packing materials can be of any suitable types and geometric configurations suitable for enhancing absorption in distillation columns and packed beds including, without limitation, Raschig ring type packing materials, Berl saddle type packing materials, intalox saddle type packing materials, tellerette type packing materials, and Pall ring type packing materials. The packing materials can be constructed of any suitable materials including, without limitation, stainless steel, ceramic, glass, quartz, and plastics.

In operation, the raw material fluid containing a low-k silicon-containing compound is directed from the supply source into the adsorption unit 10, preferably in liquid state, where the fluid contacts adsorbent material 11 including adsorbents such as those described above within the bed to facilitate removal of organic contaminants, moisture, and/or other impurities from the fluid. The fluid then passes through the filtration unit 13, where solid particulate materials are separated from the fluid by the filtration unit.

Fluid flow is selectively directed through the vaporization unit 28 by maintaining valves 18 and 61 in closed positions while maintaining valve 15 in an open position. Fluid purified within the filtration unit 13 flows to the vaporization chamber 30, via flow line 16, where impurities such as organic compounds, metals and/or metal compounds remain in liquid state and are removed from the vaporized fluid including the low-k silicon-containing material. The further purified vaporized fluid passed through the flow chamber 33 and into the condenser 34, where the fluid is condensed back to a liquid. Lighter impurities not previously removed are separated from the condensed liquid and vented via vent line 36. The condensed liquid product is passed through line 40, where the purified liquid product is then directed to container 46.

Optionally, as noted above, a select amount of the purified liquid product is diverted through line 41 into line 43, by opening valve 42, and back into the flow chamber 33. In this embodiment, the flow chamber 33 further serves as a packed bed, including packing materials that facilitate sufficient residence time and contact between the liquid flowing back into the vaporization chamber 30 and the purified vapor moving toward the condenser 34. The contacting of the two countercurrent streams facilitates absorption of impurities from the vapor into the backflowing liquid to further enhance purification of the vapor stream.

Any suitable number and types of sensors and chemical analyzers can be disposed at any one or more suitable locations within the system 2 to facilitate extraction of a fluid sample for measurement of the purity level during system operation. For example, the impurity quality of the low-k silicon-containing material flowing through the system can be monitored by taking samples after the filter 13 and/or after the condenser 34 for impurity concentration analysis. Depending upon the impurity and quality levels of the material, as measured and analyzer(s), fluid flow can be diverted by closing valve 15 and opening valve 61 to divert fluid flow to avoid the vaporization unit 28 altogether if it is determined that the purity level is sufficient and no further purification is necessary.

In addition, the raw chemical supply can also be introduced into the vaporization chamber 30 without flowing through the adsorption unit 10 (e.g., in situations where the adsorption unit needs to be regenerated). In this case, the valve 18 will be open and the valves 15 and 21 will be closed.

When the production container 46 is filled, it can be disconnected from the line 45 and replaced. To avoid contamination of the line 45 and system 2 by ambient air, the product container 46 can be located inside a glove box or a similar enclosure. Inert gas of sufficient purity, such as helium, argon, and/or nitrogen, can be used to purge the product line 45 to eliminate the potential for ambient contamination within the line. Alternatively, it is noted that the system 2 can be implemented for direct, in-line use with a semiconductor manufacturing system, such that purified low-k silicon-containing materials that are produced are delivered directly to one or more manufacturing processes rather than being collected first.

The adsorption unit 10 can be replaced with a new bed of adsorbent materials after it becomes saturated with impurities. The adsorption unit can also be regenerated in-line by flowing heated inert gas such as nitrogen, helium, and/or argon through the bed to desorb the bed. High temperature water steam could also be used for regeneration of the adsorption unit.

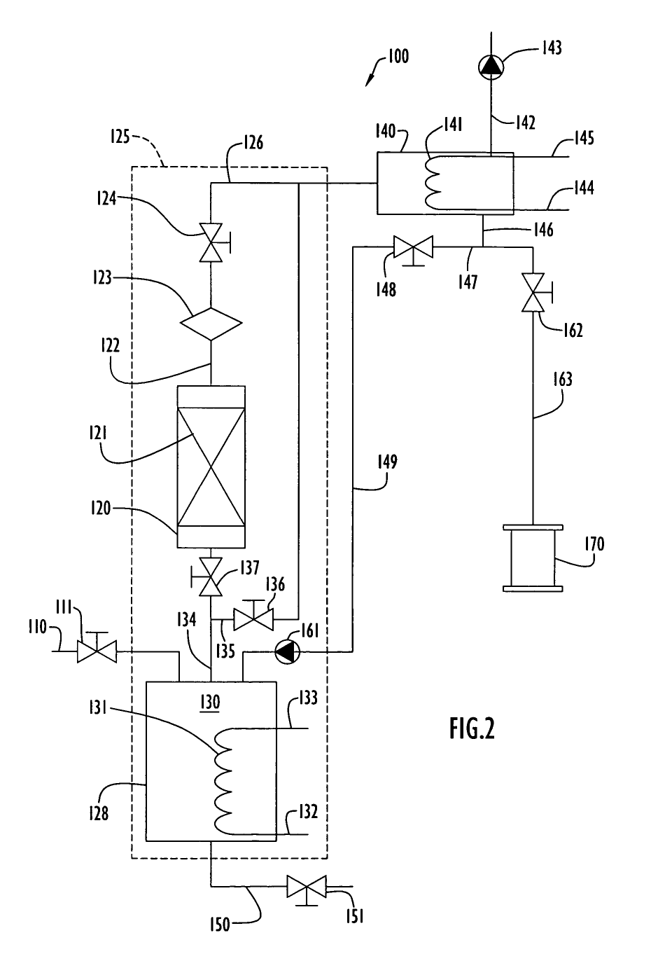

An alternative embodiment 100 is depicted in FIG. 2 for purifying low-k silicon-containing materials for use in semiconductor manufacturing processes. In this embodiment, the raw material is first directed into a vaporization unit, followed by optional adsorption of the vapor stream in an adsorption unit. Referring to FIG. 2, a raw material, preferably in liquid state and including low-k silicon-containing compounds, is transferred from a supply source (not shown) through a line 110 and a valve 111 into a vaporization unit 128 including a vaporization chamber 130. The vaporization unit 128 of the system 100 is substantially similar in design and operates under substantially similar temperature and pressure conditions as the vaporization unit described above for the system of FIG. 1.

The raw material entering the chamber 130 is vaporized therein due to heat being provided by a heating element 131 in a manner substantially similar to the heating element described above for the vaporization unit of FIG. 1. In particular, the heating element 131 can be a heating coil installed inside the vaporization chamber to have a direct contact with the liquid chemical, where heat fluid flows into the coil through the line 132 and out of the coil through line 133. Alternatively, the heating element can be a blower to blow hot air to the outside surfaces of the vaporization chamber 130 or, further still, a heated box, such that heat is transferred through the chamber surface to the liquid chemical inside the chamber. The heating element can also be an electric heat jacket installed outside of the vaporization chamber.

The temperature and pressure inside the vaporization chamber is controlled to vaporize the low-k silicon-containing materials and other volatile compounds, while leaving impurities such as organic compounds, metals and metal compounds having high boiling points as liquids within the chamber. Thus, a separation and purification of the vapor from the impurity liquids is achieved within the vaporization chamber 130. A drain line 150 is connected to the vaporization chamber 130 at the bottom of the chamber to permit waste liquid including the separated impurities to be withdrawn from the chamber 130 by opening a valve 151 disposed along the drain line 150. Once the valve 151 is opened, the waste fluid can flow out of the chamber 130 to a waste collection vessel (not shown).

The vapor produced in the vaporization chamber 130 flows up through a line 134 to an adsorption unit 120, where volatile impurities are removed by adsorption. Adsorbents 121 are provided in the adsorption unit 120 to contact the vapor. The adsorbents can be of any suitable type, such as those described above. The preferred adsorbents for use in vapor adsorption are Ambersorb® 600 (commercially available from Rohm & Haas, Philadelphia, Pa.).

After flowing through the adsorption unit, the purified low-k silicon-containing material vapor flows through a line 122 to a filter device 123 to facilitate removal of any impurity particles and/or mists from the vapor. The filter device 123 is substantially similar to the filter device described above and depicted in FIG. 1, having a pore size of no greater than about 0.5 micrometer. The vapor exiting the filter device 123 is directed through a line 126, including a valve 124 disposed along the line 126, and into the inlet of a condenser 140.

The condenser 140 condenses the purified vapor to a liquid product, while non-condensed vapor is emitted through a vent line 142 that includes a one-way check valve 143 to allow the non-condensed vapor to be vented from the condenser 140. A heating element 141 is disposed within the condenser 140 to remove heat from the chemical vapor inside the condenser, thus facilitating condensation of the silicon-containing material to a liquid. The heating element 141 is substantially similar to the condenser heating element described above for the embodiment depicted in FIG. 1. In particular, the heating element 141 can be a coil type heat exchanger in which coolant flows through line 144 to the coil and out through line 145. The heat element can also be installed outside the condenser in any suitable manner as described above to achieve sufficient cooling of the vapor within the condenser.

The condensate flows (e.g., by gravity and/or by a suitable pressure differential existing between the inside of the condenser 140 and the condenser outlet) to a flow line 146 that connects with a branch line 147. The branch line 147 connects with a valve 162 disposed at a downstream location from the flow line 146. A flow line 163 also connects with the valve 162 and leads to a product container 170 to receive purified liquid product containing the low-k silicon-containing material from the condenser 140.

A selected portion (e.g., some or all) of the condensate from the condenser 140 can be diverted back to the vaporization unit 130 in a similar manner as described above for the embodiment of FIG. 1 (e.g., during initial system start-up and/or when the product quality is low, as determined by impurity concentrations that are high). The flow line 147 is connected to a valve 148 disposed at a downstream location from the flow line 146, and the valve 148 is further connected to a flow line 149. The flow line 149 extends to and connects with the vaporization chamber 130. Thus, diversion of a selected portion of the condensate from the condenser 140 back to the purification chamber 130 is achieved by selective manipulation of valves 148 and 162. A one way check-valve 161 is optionally disposed along the flow line 149 to permit one way flow of condensate from the condenser to the vaporization chamber while preventing flow of vapor from the vaporization chamber into a significant portion of the flow line 149 (e.g., when little or no liquid is flowing from the condenser through the flow line 149).

The system 100 further includes a by-pass feature to permit selective by-pass of the adsorption unit 120 and filter device 123 for vapor fluids exiting the vaporization chamber 130. In particular, a branching by-pass line 135 connects with flow line 134 at a suitable location between the vaporization chamber 130 and the adsorption unit 120. The by-pass line 135 includes a valve 136 disposed along the line 135 and further extends between flow line 134 and flow line 126. In addition, a valve 137 is disposed along flow line 134 at a location between the connection point with by-pass line 135 and the inlet of the adsorption unit 120. In situations where it is desirable to eliminate the processing steps of adsorption and filtering (e.g., when vaporization and condensation are sufficient to purify the material, and/or when maintenance is required for the adsorption unit or the filter unit), valve 136 is opened and valves 137 and 124 are closed to selectively divert the flow of the vapor stream directly to the condenser 140 after emerging from the vaporization unit 128.

To avoid condensation of any components in the vapor stream prior to the stream reaching the condenser 140, the vaporization chamber 130, by-pass line 135, the adsorption unit 120, line 122, the filter 123, and at least a portion of line 126 (which feeds the filtered vapor stream to the condenser 140) can be thermally insulated in any suitable manner from the ambient environment. For example, these components can be wrapped or covered with isolation materials such as the foam materials. Alternatively, these components can isolated within an insulated enclosure (generally indicated by the dashed lines 125 of FIG. 2) to substantially minimize or prevent loss of heat from these components. The enclosure can further be heated in any suitable manner to selected temperatures above ambient temperatures (e.g., about 1° C. higher than the boiling temperature of the low-k silicon-containing material being processed at the system pressure) so as to ensure the material stream substantially remains as a vapor prior to entering the condenser.

Optionally, the system 100 can further include a packed bed arrangement that is similar in design and function as the packed bed described above in relation to the flow chamber 33 of the system of FIG. 1. In particular, the by-pass line 149 can be modified to include packing material of any suitable type, such as the packing material described above, and suitable valves can be installed within the by-pass line to facilitate selective countercurrent flow of vapor (from the vaporization chamber 130 to the condenser 140) and condensate (from the condenser 140 to the vaporization chamber 140), which will enhance absorption of impurities from the vapor stream into the condensate so as to further purify the vapor stream when such countercurrent flow is enabled during system operation.

The purification systems described above remove impurities in silicon-containing materials by at least one of adsorption, filtration, vaporization, condensation and absorption. In particular, these systems are highly effective in purifying low-k silicon-containing compounds that exist in liquid state at ambient temperature and pressure conditions including, without limitation, trimethylsilane, tetramethylsilane, dimethyldimethoxysilane, tetramethylcyclotetrasiloxane, octamethylcyclotetrasiloxane, dimethylphenyl silane, and dimethyldivinyl silane.

The impurity concentrations of silicon-containing raw or starting materials can be reduced, utilizing the systems and methods of the present invention, by at least 2 to 3 orders of magnitude as measured by the final impurity concentrations of the product. Depending on the quality of the raw materials provided for purification, the combination of one or more of adsorption, filtration, vaporization, condensation and/or absorption, low-k silicon-containing material products can be generated in accordance with the present invention having impurity concentrations no greater than about 1 ppm, and in many situations the impurity concentrations of the purified products are no greater than about 100 parts per billion (ppb), and further still no greater than about 10 ppb. Metallic impurity concentrations that are within the raw material in concentrations of 1 ppm or even higher can be reduced within the purified products to concentrations no greater than about 10 ppb, and further still to concentrations no greater than about 1 ppb.

The following examples show the effectiveness of a purification system in purifying a low-k silicon-containing material in accordance with the present invention. In particular, a system was employed utilizing only an adsorbent bed, and the raw material to be purified was tetramethyl silane.

### EXAMPLE 1

An adsorption unit was assembled utilizing a column of 2.54 centimeter (1 inch) inner diameter and 36.8 centimeters (14.5 inches) in length was packed with about 80 grams of Ambersorb® 563 adsorbent material for removing organic impurities from tetramethyl silane. Liquid tetramethyl silane flowed as influent upward through the column at a flow rate of about 20 milliliters/minute. The concentrations of tetrahydrofuran and toluene in the influent tetramethyl silane were spiked to 24,000 ppm (weight) and 4,570 ppm (weight), respectively. The adsorption unit was operated at ambient conditions of 24° C. and 270 kPa.

The concentrations of the tetrahydrofuran and toluene were measured periodically in the effluent stream from the adsorption unit utilizing a Varian model CP-3800 gas chromatograph having a detection limit of 150 ppb. The adsorption unit removed these impurities to sufficient levels that were below the detection limit of the gas chromatograph, indicating that the effluent stream containing no more than about 150 ppb (weight). In addition, the adsorption unit was operated for a period of 12.5 minutes before concentration levels of the two impurities started to increase within the effluent stream that were detectable by the gas chromatograph. At this time, it was determined that the adsorbent material in the adsorption unit was saturated with 3.92 grams of tetrahydrofuran and 0.78 grams of toluene.

Thus, the present example demonstrates the effectiveness of utilizing an adsorption unit to remove high levels of organic impurities from a liquid low-k silicon-containing material.

### EXAMPLE 2

The adsorption unit of the previous example was regenerated after its saturation by heating the unit to a temperature about 200° C. while purging the unit with nitrogen gas at a flow rate of 3 liters/minute for a period of six hours. After this purging process, the material stream spiked with impurities as described in the previous example was flowed through the unit, and the unit was determined to be fully regenerated and performed in the same manner as described in the previous example prior to saturation of the adsorbent material.

### EXAMPLE 3

The process as described in Example 1 was performed in the same manner as the present example, with the exception that the adsorption unit was packed with activated carbon grains instead of Ambersorb® 563 adsorbent material and the concentrations of tetrahydrofuran and toluene in the influent tetramethyl silane were spiked to 5,048 ppm (weight) and 4 ppm (weight) respectively. The influent stream was directed through the column as the same flow rate as described in Example 1, and impurity levels of toluene and tetrahydrofuran in the effluent were not detected for a period of 30 minutes. At the point in time when the gas chromatograph began detecting impurity concentrations, the process was halted and the amount of impurities within the adsorbent material was measured. It was determined that at least 2.8 grams of tetrahydrofuran and at least 2.06 milligrams of toluene were adsorbed in the activated carbon grains and were thus removed from the tetramethyl silane during the process.

Thus, the systems and methods of the present invention effectively purify silicon-containing materials for use in semiconductor manufacturing applications by combining one or more purification steps such as adsorption, filtration, vaporization, condensation, absorption and/or filtration. The combination of two or more purification steps is chosen based upon the starting raw materials utilized, the purity of such starting raw materials, and the degree of purification desired. Thus, the present invention is not limited to the specific systems described above in FIGS. 1 and 2 or the examples. Rather, any suitable system and method that combines one or more of these purification techniques in any suitable arranged can be utilized to purify silicon-containing materials.

Having described novel systems and methods for purification of silicon-containing materials, it is believed that other modifications, variations and changes will be suggested to those skilled in the art in view of the teachings set forth herein. It is therefore to be understood that all such variations, modifications and changes are believed to fall within the scope of the present invention as defined by the appended claims.

1. A method of purifying a silicon-containing material comprising:
directing the silicon-containing material in a liquid state through an adsorption unit including an adsorbent material to facilitate adsorption of at least one component from the silicon-containing material.

2. The method of claim 1, wherein the silicon-containing material is a low-k material comprising at least one of trimethylsilane, tetramethylsilane, dimethyldimethoxysilane, tetramethylcyclotetrasiloxane, octamethylcyclotetrasiloxane, dimethylphenyl silane, and dimethyldivinyl silane.

3. The method of claim 1, further comprising:
directing the silicon-containing material stream emerging from the adsorption unit through a filter unit to facilitate removal of particulate materials from the silicon-containing material stream.

4. The method of claim 3, further comprising:
directing the silicon-containing material stream emerging from the adsorption unit through a vaporization unit to facilitate at least partial vaporization of the silicon-containing material stream to form a silicon-containing material vapor stream.

5. The method of claim 4, wherein a portion of the silicon-containing material stream remains in a liquid state within the vaporization unit and is separated from the silicon-containing material vapor stream.

6. The method of claim 5, further comprising:
selectively removing the portion of the silicon-containing material stream that remains in a liquid state from the vaporization unit via a drain line connected with the vaporization unit.

7. The method of claim 4, further comprising:
directing the silicon-containing material vapor stream to a condenser to facilitate condensation of the vapor stream to form a silicon-containing material product stream.

8. The method of claim 7, further comprising:
directing the silicon-containing material vapor stream through a chamber disposed between the vaporization unit and the condenser, the chamber including packed materials disposed therein; and
directing a portion of the silicon-containing material product stream to the chamber to facilitate a countercurrent flow and contact within the chamber and between the silicon-containing material product stream and the silicon-containing material vapor stream.

9. The method of claim 7, further comprising:
providing a by-pass line to selectively divert the silicon-containing material stream emerging from the adsorption unit to a location downstream from the vaporization unit and the condenser during system operation.

10. The method of claim 1, further comprising:
directing the silicon-containing material that has been processed within the adsorption unit to a semiconductor manufacturing process.

11. The method of claim 1, wherein the adsorbent material comprises a carbonaceous material formed by pyrolysis of a sulfonated styrene-divinylbenzene macroreticular ion exchange resin.

12. A method of purifying a silicon-containing material comprising:
directing the silicon-containing material through at least two of the following: an adsorption unit including an adsorbent material to facilitate adsorption of at least one component from the silicon-containing material, a filter unit to remove particulate material from the silicon-containing material, a vaporization unit to facilitate at least partial vaporization of the silicon-containing material stream to form a silicon-containing material vapor stream, and a condenser to condense the silicon-containing material from a vapor state to a liquid state.

13. The method of claim 12, wherein the directing step includes:
directing the silicon-containing material to the vaporization unit; and
directing a silicon-containing material stream emerging from the vaporization unit to the adsorption unit.

14. The method of claim 13, wherein the adsorbent material of the adsorption unit comprises a carbonaceous material formed by pyrolysis of a sulfonated styrene-divinylbenzene macroreticular ion exchange resin.

15. The method of claim 13, wherein the directing step further includes:
directing the silicon-containing material emerging from the adsorption unit to the filter unit.

16. The method of claim 15, wherein the silicon-containing material emerges from the vaporization unit as a vapor stream and is maintained as a vapor stream as the stream is directed through the adsorption unit and the filter unit.

17. The method of claim 16, wherein the directing step further includes:
directing the silicon-containing material vapor stream to the condenser.

18. The method of claim 17, further comprising:
selectively diverting the flow of the silicon-containing material vapor stream emerging from the vaporization unit directly to the condenser so as to by-pass the adsorption unit and the filter unit.

19. The method of claim 12, wherein the silicon-containing material is supplied to the directing step in a liquid state.

20. The method of claim 19, wherein the directing step includes:
directing the liquid silicon-containing material to the adsorption unit; and
directing the liquid silicon-containing material emerging from the adsorption unit to the vaporization unit.

21. The method of claim 12, wherein the silicon-containing material is a low-k material comprising at least one of trimethylsilane, tetramethylsilane, dimethyldimethoxysilane, tetramethylcyclotetrasiloxane, octamethylcyclotetrasiloxane, dimethylphenyl silane, and dimethyldivinyl silane.

22. The method of claim 12, further comprising:
providing the silicon-containing material that has been processed in the directing step to a semiconductor manufacturing process.

23. A system for purifying a silicon-containing material comprising:
a supply source for supplying silicon-containing material in a liquid state; and
at least one purification unit in fluid communication with the supply source to receive the silicon-containing material in the liquid state, the at least one purification unit comprising at least one of an adsorption unit including an adsorbent material to facilitate adsorption of at least one component from the silicon-containing material, and a vaporization unit to facilitate at least partial vaporization of the silicon-containing material stream to form a silicon-containing material vapor stream.

24. The system of claim 23, wherein the at least one purification unit includes the adsorption unit and the vaporization unit disposed at a downstream location from the adsorption unit, and the system further comprises:
a filter unit disposed downstream from the adsorption unit and upstream from the vaporization unit to facilitate removal of particulate material from the silicon-containing material in the liquid state.

25. The system of claim 24, wherein the adsorbent material of the adsorption unit comprises a carbonaceous material formed by pyrolysis of a sulfonated styrene-divinylbenzene macroreticular ion exchange resin.

26. The system of claim 24, further comprising:
a condenser disposed downstream from the vaporization unit to receive a silicon-containing material vapor stream from the vaporization unit and condense at least a portion of the vapor stream to form a silicon-containing liquid product.

27. The system of claim 26, further comprising:
a flow chamber disposed downstream from the adsorption unit and upstream from the condenser to facilitate flow of the vapor stream from the adsorption unit to the condenser via the flow chamber; and
a return line connected between an outlet of the condenser and the flow chamber, the return line being configured to selectively deliver at least a portion of the silicon-containing liquid product to the flow chamber in a countercurrent flow direction with respect to the vapor stream.

28. The system of claim 27, wherein the flow chamber includes packing material disposed within the flow chamber.

29. The system of claim 26, further comprising:
a by-pass line in fluid communication with an outlet of the adsorption unit and configured to facilitate selective diversion of the silicon-containing material in the liquid state to a location disposed downstream from the condenser so as to by-pass the vaporization unit and the condenser during system operation.

30. The system of claim 26, further comprising:
a by-pass line disposed downstream from the supply source and configured to facilitate selective diversion of the silicon containing material from the supply source directly to the vaporization unit so as to by-pass the adsorption unit and the filter unit during system operation.

31. The system of claim 23, wherein the at least one purification unit includes the vaporization unit and the adsorption unit disposed at a downstream location from the vaporization unit, and the system further comprises:
a filter unit disposed downstream from the adsorption unit to facilitate removal of particulate material from the silicon-containing material in the liquid state.

32. The system of claim 31, wherein the vaporization unit, adsorption unit and filter unit are disposed within an insulation section to maintain a silicon-containing material vapor stream flowing from the vaporization unit and through the adsorption unit and filter unit, the system further comprising:
a condenser disposed downstream from the filter unit to receive the silicon-containing material vapor stream and condense at least a portion of the vapor stream to form a silicon-containing liquid product.

33. The system of claim 32, further comprising:
a by-pass line disposed downstream from the vaporization unit and configured to selectively divert the silicon-containing material vapor stream from an outlet of the vaporization unit directly to the condenser so as to by-pass the adsorption unit and the filter unit.

34. The system of claim 32, further comprising:
a return line connected between an outlet of the condenser and the vaporization unit, the return line being configured to selectively deliver at least a portion of the silicon-containing liquid product to the vaporization unit during system operation.

35. The system of claim 23, wherein the supply source delivers a low-k silicon-containing material comprising at least one of trimethylsilane, tetramethylsilane, dimethyldimethoxysilane, tetramethylcyclotetrasiloxane, octamethylcyclotetrasiloxane, dimethylphenyl silane, and dimethyldivinyl silane.

36. A system for purifying a silicon-containing material comprising:
a supply source for supplying silicon-containing material in a liquid state; and
a means for purifying the silicon-containing material in a liquid state by adsorption of at least one component from the silicon-containing material.

37. The system of claim 36, wherein the supply source delivers a low-k silicon-containing material comprising at least one of trimethylsilane, tetramethylsilane, dimethyldimethoxysilane, tetramethylcyclotetrasiloxane, octamethylcyclotetrasiloxane, dimethylphenyl silane, and dimethyldivinyl silane.
